(19) United States
(12) Patent Application Publication
(10) Pub. No.: US 2023/0147212 A1
(43) Pub. Date: May 11, 2023

(54) METHOD FOR DETERMINING AN AGING STATE OF AT LEAST ONE CELL OF A BATTERY

(71) Applicant: Dr. Ing. h.c. F. Porsche Aktiengesellschaft, Stuttgart (DE)

(72) Inventor: Eike Epler, Stuttgart (DE)

(73) Assignee: Dr. Ing. h.c. F. Porsche Aktiengesellschaft, Stuttgart (DE)

(21) Appl. No.: 17/947,284

(22) Filed: Sep. 19, 2022

(30) Foreign Application Priority Data
Nov. 5, 2021 (DE) 10 2021 128 800.2

(51) Int. Cl. G01R 31/392; G01R 31/396

(52) U.S. Cl. CPC G01R 31/392; G01R 31/396

(57) ABSTRACT

A method for determining an aging state of at least one cell of a battery. The method includes the step receiving a large amount of operating data relating to the at least one cell of the battery via a memory unit, wherein the operating data can be assigned to a specific point in time. The received operating data is stored in the memory unit with a timestamp which corresponds to the respectively assigned point in time. An aging state of the at least one cell of the battery is calculated using a processor while interdependently taking into account multiple operating data having a common timestamp. The method makes it possible to estimate an aging state using a multidimensional database.

### CROSS-REFERENCE TO RELATED APPLICATION

This application claims priority to German Patent Application No. 10 2021 128 800.2, filed Nov. 5, 2021, the content of such application being incorporated by reference herein in its entirety.

### FIELD OF THE INVENTION

The invention relates to a method for determining an aging state of at least one cell of a battery, a measuring apparatus including such a method for a battery of a motor vehicle, a motor vehicle comprising such a measuring apparatus, a computer program including such a motor vehicle and a computer program product comprising such a computer program.

### BACKGROUND OF THE INVENTION

Battery-electric motor vehicles are becoming increasingly popular in the market, partly due to government subsidies and the ever more stringent restrictions on internal combustion engines. The range of the motor vehicles is a strong incentive to buy, whereby the range depends primarily on the capacity and the aging state of the (traction) battery. The capacity of the battery is a physicochemical limit that is already well understood and easy to model, whereas the aging state of a battery can currently only be modeled inadequately. In order to be able to maintain the range of a battery-electric motor vehicle even over a longer period of use, reliable predictions of the aging states of a battery, or the modeling of the aging state, are needed. The aging state of a battery depends on a variety of factors that are intricately interconnected. For example, the outside temperature, the driver’s driving behavior and other operating data are relevant to the aging state in addition to the SoC (state of charge).

The aging state of the battery is usually modeled on the basis of one-dimensional observations or the inclusion of operating data. For example, a temporal series of measured values is integrated and the integral is stored.

### SUMMARY OF THE INVENTION

The features described herein can be combined in any technically meaningful manner, whereby the explanations from the following description and features from the figures, which include additional configurations of the invention, can be used as well.

The invention relates to a method for determining an aging state of at least one cell of a battery, comprising the following steps:
a. receiving a large amount of operating data relating to the at least one cell of the battery via a memory unit, wherein the operating data can be assigned to a specific point in time;
b. storing the received operating data in the memory unit with a timestamp which corresponds to the respectively assigned point in time; and
c. calculating an aging state of the at least one cell of the battery by means of a processor while interdependently taking into account multiple operating data having a common timestamp.

Unless explicitly stated otherwise, ordinal numbers are used in the preceding and the following description only for the purposes of clear distinction and do not reflect any order or ranking of the designated components. An ordinal number greater than one does not imply that another such component has to necessarily be present.

In the methods known from the state of the art, there is no temporal linking of the operating data, so that the temporal relationship is not known or is known only insufficiently. Any load paths over the service life of a battery are not or only insufficiently reproducible. According to our observations, however, the temporal relationship of the operating data is essential for a realistic modeling of an aging state of a battery.

It should be noted that the method proposed here can be used not only for a traction battery of a motor vehicle, but also for other batteries, for example also outside of a motor vehicle application, such as for a laptop battery or a smartphone battery.

A method is proposed here to determine the aging state of a cell, multiple or all cells of a battery over the service life of said battery. The aging state is understood here to mean the decrease in a charge capacity of a battery over a service life. Due to charging and discharging cycles (current integrals) or simple storage, batteries undergo aging processes that affect the capacity in such a way that the performance capacity of a battery and/or the change in power loss under identical load decreases over the course of its service life.

It should be noted that a battery here refers to an electrical accumulator. An electrical accumulator is a rechargeable battery. The cell or also galvanic cell of a battery is the smallest energy storage unit within the battery, whereby the stored chemical energy can be converted into electrical energy via the electrochemical redox reaction. In a battery, a plurality of cells are typically interconnected in such a way that their voltages and/or capacities add up. In a traction battery, (at least a large part of the) stored electrical energy is converted into kinetic energy by an electric drive motor, and deceleration is usually recuperated, i.e., used to charge the traction battery. The method can therefore be used both at cell level and at battery level.

The memory unit is part of a battery management system, an on-board computer and/or a backend or a cloud, for example, and is connected to the cell or the battery via a (possibly wireless) data connection, so that the memory unit receives the operating data from the cell or the battery, for example in a self-triggering clocked manner and/or controlled by means of an associated processor. The memory unit is disposed within, or communicatively connected, to a battery. The operating data is stored in the memory unit assigned to a specific point in time and is backed up in the memory unit.

In Step a. of the method for determining an aging state of at least one cell of a battery, a memory unit receives a large amount of operating data relating to at least one cell of a battery. The operating data is assigned to a specific point in time. All or some of the operating data is collected at a small clock rate, for example in the range of less than one second, preferably in the range of a few milliseconds, for example every 1 ms (one millisecond) to 10 ms. In a preferred embodiment, the operating data is processed raw or only for digital processing and, if necessary, suitably filtered or smoothed. In another embodiment, integrated measured values are used as the operating data (as already known, for example).

All of the operating data is preferably synchronized, for example always collected at the same time (in a narrow time window of a few milliseconds). Physical quantities that change more slowly (for example a temperature) are monitored at a lower clock rate, for example, than physical quantities that change more quickly (for example a voltage). In an advantageous embodiment, the same point in time can be assigned to a large amount or all of the operating data collected at the same time with sufficient accuracy.

The operating data includes the temperature of the cell and/or the battery and/or the environment of the battery, for example, the electrical charge (SoC, or relative to the nominal capacity SoH (state of health)) and the electrical voltage across the cell and/or across the battery, torque requests to an electric drive motor and/or accelerations of the electric drive motor.

It should be noted that every collected measured value is assigned a defined point in time, i.e., the operating date, and that this assignment is also retained in the further processing. The assignment of a specific point in time to the operating data makes it possible to show a temporal sequence of the operating data.

In Step b. of the method, the received operating data is stored with a timestamp which corresponds to the respectively assigned point in time. From the received operating data, vectors or tuples of operating data are provided with a respective timestamp in Step b., for example, so that a temporal correlation emerges from the various vectors or tuples. The timestamps make it possible to reproduce and sort a load path of a cell and/or battery, for example. It should be noted that tuples referred to in the following mathematically include vectors.

In Step c. of the method, an aging state of at least one cell of a battery is calculated by means of a processor, taking into account the interdependency of the operating data with the associated timestamps. Interdependency is understood to mean mutual dependency, so that the capacity of the battery depends not only on the cell voltage, for example, but also on external conditions such as the temperature or the driving behavior (i.e., power demand) of the driver. The timestamps thus provide each tuple with a reproducible temporal dependency within the tuple and/or between at least two tuples.

Within a tuple, the various operating data is plotted at a common point in time or timestamp, whereby the operating data exhibits an interdependency. The cell voltage, i.e., the charge difference within a cell of the battery, for example, depends not only on the selection of the electrode pairs, but also on the external and the internal temperature of the cell or the battery and on the relaxation time of the cell after a load (strong acceleration of the electric drive motor). The interdependencies within a battery are furthermore also mapped to a timestamp in a tuple, so that the SoC of the battery, for example, has an effect on the cell voltage of a single cell.

The various operating data is plotted at two different points in time or timestamps between at least two tuples, whereby the operating data exhibits an interdependency across the timestamps. The aging state of a cell of a battery depends on the power output over the elapsed period of time between the two timestamps, for example, so that the voltage within a tuple at a predefined second timestamp also depends on the acceleration of an electric drive motor at a preceding first timestamp. A battery also decreases its voltage and/or capacity over the course of its service life as a result of diffusion effects. In the case of extended idle time, i.e., a time without discharging cycles and charging cycles, the described effects are only minimal, so that an extrapolated aging state, for example, does not occur until later. Consequently, a continuous measurement of the operating data across a plurality of points in time and a consideration of the interdependency across the points in time as proposed here is advantageous, so that, even in the event of extended idle time, the aging state can be depicted clearly.

In Step c., the tuples are arranged in such a way that they span a matrix, for example, or are stored in the manner of a matrix, whereby the timestamps enable temporal indexing within the matrix. The matrix can thus be interpreted as an aging model of the battery, which is calculated by means of the processor and is expanded at each new point in time or timestamp.

Another effect is that this enables compression, for instance if a value is (at least almost) constant across a plurality of tuples. The time interval between receiving the operating data is selected such that there are only 20 ms (twenty milliseconds) between the timestamp and the timestamp, for example, so that, between two states of the battery that are free of a load or a change in load (for example a constant ambient temperature), no or only a very small change in the operating data has occurred. This constancy within the operating data between two timestamps is captured by the processor and likewise compressed in Step c. such that, if the operating data fluctuates within a predefined tolerance range, the operating data is considered constant or the mean value of the fluctuation amounts is determined and calculated as new operating data. The constancy and the resulting compression of the volume of data makes it possible to reduce the (digital) volume of data of the aging state to be kept available within the matrix.

In an advantageous embodiment of the method, it is further proposed that the calculation in Step c. be carried out on the basis of empirical and/or phenomenological data stored in the memory unit and/or available to the memory unit.

To link the interdependency between the operating data within a timestamp and calculate the aging state, it is proposed here that the calculation be based on empirical and/or phenomenological data. This data is stored in the memory unit and/or is available to the memory unit, for example via a data interface with a cloud or a backend. The data establishes links between the received operating data; in addition to the temperature, for example, the prevailing air pressure is also a relevant factor that contributes to a new aging state. It has been shown that previous load times of the battery with incomplete relaxation times, i.e., recovery times of the cell and/or the battery, are likewise relevant in the interdependency for the calculation of the aging state in Step c. and are therefore taken into account in the calculation.

The empirical and/or phenomenological data is not the same as the operating data, because the operating data represents purely physical measured values and the interdependency of the measured values within a point in time and/or across a point in time or timestamp can be depicted by means of the empirical and/or phenomenological data. Dendrite formation within a cell or a battery, for example, cannot be measured or can only be measured with great effort and can usually only be measured at a late (possibly too late) point in time. Since (at least some of the) relevant boundary conditions, i.e., the physical measured values, are known, this phenomenon can nonetheless be predicted, at least in part, with a certain degree of probability. These boundary conditions are complex, however, and some relationships are still unknown. The here proposed matrix of tuples with their operating data having a respective timestamp makes it possible to observe a very large number of events and determine further constellations of boundary conditions on the basis of the temporal resolution. Even known relationships that can be mapped on the basis of experiments or experience in a characteristic diagram or also by means of a polynomial, for example, are more exact as a result of the temporal resolution or applicable at all (as a result of the multidimensionality).

In an advantageous embodiment of the method, it is further proposed that the calculation in Step c. be carried out using a machine learning algorithm.

It should be noted that, in one embodiment, the method can be modified using an algorithm based on the so-called machine learning algorithm (for example deep learning or machine learning). Such a machine learning algorithm is already known, for example from the fields of speech recognition and/or speech processing and facial recognition, wherein they are based on volumes of data that cannot be adequately managed by humans and/or on rules that are known only insufficiently or not at all. Similar to a finite element algorithm, such an algorithm is trivial in the smallest sense but, due to the complexity (in this case primarily the number of factors and the high temporal resolution), the tasks are unsolvable for a human or solvable only with an unjustifiable expenditure of time. Examples of known algorithms or applicable program libraries are TensorFlow®, Keras and Microsoft® Cognitive Toolkit. For instance, the method learns how the user of a motor vehicle behaves while driving and is thus able to calculate the aging state more accurately. The learning is active over the service life of the cell or the battery, active over a service life of the drive train, or also even part of an overarching body of knowledge that is stored, for example, by a vehicle developer in a proprietary or generally accessible manner.

According to this proposal, the calculation is carried out by means of the machine learning algorithm on the basis of previously trained (i.e., known) aging states of other cells or batteries or the like from earlier points in time, so that an interdependency between the various operating data within a timestamp and/or across a plurality of timestamps can be learned automatically using the machine learning algorithm. This trained machine learning algorithm is stored and initialized in a memory unit, for example in a battery management system, so that the calculation of the aging state is carried out in the processor by means of the machine learning algorithm and an extrapolation of the aging state can thus be calculated as well.

Due to the trained machine learning algorithm, a memory unit in one embodiment is free of empirical and/or phenomenological data representing the interdependency, because the learning or training of the machine learning algorithm detects these interdependencies automatically and creates links. It should be noted that the machine learning algorithm presents these links to human users in a way that is comprehensible only to a very limited extent, but also learns interdependencies that a human user may not have noticed. The latter is primarily the case here, because the volume of operating data, and in particular their (potential) interdependency and the temporal resolution, (at least preferably) is very high and the volume of data is thus unmanageably large for a human. Known, for example, is a one-dimensional calculation of a temporal sequence of a single piece of operating data 1 (i.e., measured value) using the hidden Markov method. This calculation is already complex and does not allow the interdependent (but only the parallel) consideration of multiple dimensions.

In an alternative embodiment, the aging state is calculated in Step c. using the machine learning algorithm and the empirical and/or phenomenological data stored or accessible in the memory unit. In this embodiment, therefore, an untrained or little-trained machine learning algorithm can be used as well, because it uses the empirical and/or phenomenological data in machine learning during operation of the cell or the battery (for example assigned purely locally to a single battery). This may be a meaningful first approach to learning and should preferably be verified with real-world data. In one type of application, the predictions of the machine learning algorithm become comprehensible to a human and/or the observations of the boundary conditions are made more precise.

According to a further aspect, a measuring apparatus for a battery of a motor vehicle is proposed, comprising at least the following components:
at least one sensor device for acquiring operating data relating to at least one cell of the battery;
at least one memory unit for storing operating data from the at least one sensor device; and
at least one processor for processing the operating data,
wherein the measuring apparatus is configured to carry out a method according to an embodiment according to the above description.

A measuring apparatus is now proposed here, whereby the measuring apparatus is configured for a battery of a motor vehicle.

The measuring apparatus comprises at least one sensor device for acquiring operating data, whereby the operating data is associated with at least one cell of the battery. The sensor device is therefore preferably connected to a plurality of cells of the battery, so that the operating data of the entire battery can be acquired. The cells can alternatively be observed alone in the group or alone in the overall view of the battery using the sensor device.

In one embodiment, the sensor device comprises a plurality of sensors that determine the operating data. The sensors determine the electric voltage within a cell, for example, or the temperature or the air pressure inside and/or outside the cell. In this embodiment, the sensor device is configured such that the memory unit receives the determined operating data from the sensor device in Step a. of the method.

In a preferred embodiment, the sensor device is free of sensors and is merely connected to the sensors communicatively and in a separable manner. In this embodiment, the sensors are fixedly connected to the cells of a battery to be measured, whereby the sensor device preferably actively initializes a measurement. A respective point in time is preferably defined by means of the sensor device in that a triggering of the respective measurement or an arrival of the sensor measured values in the sensor device defines the respective point in time (and timestamp).

It is furthermore proposed here that the measuring apparatus comprises a memory unit for storing operating data. The memory unit stores the operating data in such a way that the operating data can be used in Step c. of the method to calculate an aging state. The memory unit is communicatively connected to the sensor device. The memory unit is configured such that, in a method according to the above description, it receives the operating data acquired by means of the sensor device in Step a. already provided with a timestamp, whereby the associated point in time is defined by means of the triggering or receipt of the sensor measured values by the sensor device. In a later Step c., the operating data is stored by means of the memory unit in such a way that it can be assigned with the first timestamp associated with the first point in time and can be arranged temporally, for example in a matrix and/or tuple. Clocking and sequencing are carried out by a processor.

In one embodiment, the memory unit is disposed centrally in the motor vehicle (for example in a battery management system, an on-board computer, or a backend), so that the operating data is stored within the measuring apparatus or the memory unit. The memory unit is preferably communicatively connected to the sensor device and/or the battery or the motor vehicle via a wire.

In an alternative embodiment, at least a portion of the memory unit is disposed remotely, so that the operating data is stored outside the motor vehicle. In this embodiment, the memory unit is communicatively connected to the measuring apparatus. The memory unit is disposed in a cloud, for example, so that the operating data is stored outside the motor vehicle. The memory unit is communicatively connected to the measuring apparatus in such a way that the operating data can be stored and accessed in the cloud.

The measuring apparatus further comprises a processor for processing the operating data, whereby the processor is communicatively connected to the memory unit. The operating data stored by means of the memory unit can be processed by the processor in such a way that an aging state of at least one cell of a battery can be calculated. The processor is configured such that an interdependency of the operating data within a timestamp and/or across a timestamp is taken into account in Step c. of the method. The aging state of the at least one cell of a battery can be thus be calculated using empirical and/or phenomenological data which can be accessed in the memory unit for the processor and/or a machine learning algorithm which can likewise be accessed in the memory unit for the processor.

The processor is preferably furthermore configured such that the operating data can be compressed. When the operating data is compressed, the fluctuations in the operating data across the timestamps can be detected by the processor. If the fluctuations of the operating data across a plurality of timestamps are within a predefined tolerance range, the processor is configured in such a way that a single value, in each case a deviation or a mean value of the operating data for the time interval, is formed in Step c., so that the volume of data of the operating data can be reduced.

The measuring apparatus is configured such that the method for determining an aging state of at least one cell of a battery can be carried out. Step a. is carried out by means of the sensor device and Step b. is carried out by means of the memory unit, so that Step c. can ultimately be carried out by means of the processor.

According to a further aspect, a motor vehicle is proposed which comprises a drive train and at least one drive wheel, wherein the drive train includes an electric drive motor and a traction battery for propulsion of the motor vehicle,
wherein the electric drive motor which is supplied with electrical voltage by the traction battery is connected to the at least one drive wheel in a torque-transmitting manner,
wherein the motor vehicle further comprises a control device, by means of which a method according to an embodiment according to the above description can preferably be carried out by means of a measuring apparatus according to an embodiment according to the above description.

The motor vehicle comprises an electric or electrified drive train, which is designed in a conventional manner, for example, or can alternatively at least be operated in a conventional manner. The motor vehicle can be moved by means of the at least one drive wheel (for example two wheels of a common wheel axle, preferably of two wheel axes, for example as an all-wheel drive). The control device is a component of a bus system, for instance, or is the bus system. According to an embodiment, the control device is managed remotely or is communicatively connected to remote control units. In one embodiment, the control device is a portion of or is itself a central control unit, whereby preferably only the at least one necessary measuring apparatus is disposed remotely at that traction battery. The remote or central control unit, which comprises or is formed by the control device, is a so-called on-board computer of the motor vehicle, for example. In a preferred embodiment, the measuring apparatus is designed such that it is configured to carry out the method for determining an aging state of a cell in a battery.

According to a further aspect, a computer program is proposed, comprising

a computer program code, wherein the computer program code can be executed on at least one computer such that the at least one computer is prompted to carry out the method according to an embodiment according to the above description, wherein at least one unit of the computer:
is disposed in the motor vehicle; and/or
is configured to communicate with a cloud in which preferably at least part of the computer program code is provided.

The method described here is computer-implemented according to this embodiment. The computer-implemented method is stored as computer program code, whereby the computer program code, when executed on a computer, prompts the computer to carry out the method according to an embodiment according to the preceding description.

The computer-implemented method is realized by a computer program, whereby the computer program comprises the computer program code, whereby the computer program code, when executed on a computer, prompts the computer to carry out the method according to an embodiment according to the preceding description. Computer program code refers synonymously to one or more instructions or commands that prompt a computer or a processor to carry out a series of operations representing an algorithm and/or other processing methods, for example.

The computer program can preferably be carried out partially or entirely on a server or a server unit of a cloud system, a handheld device (for example a smartphone), and/or on at least one unit of the computer. The term server or server unit refers here to a computer that provides data and/or operational services or services to one or more other computer-assisted devices or computers and thus forms the cloud system. The at least one unit of the computer in a motor vehicle is a battery management system, an on-board computer or an external control unit, for example, that is connected to or (at least partially) comprises a memory unit and a processor. Alternatively or additionally, the at least one unit of the computer is configured to communicate with at least one server and/or a cloud, whereby the server and/or the cloud is disposed on-site at a manufacturer of the computer, for example.

The terms cloud system or computer are used here synonymously to the devices known in the state of the art. A computer therefore comprises one or more general purpose processors (CPU) or microprocessors, RISC processors, GPU, and/or DSP. The computer comprises additional elements such as, for example, memory interfaces or communication interfaces. Optionally or additionally, the terms refer to a device that is capable of executing a provided or integrated program, preferably using a standardized programming language (for example C++, JavaScript or Python), and/or controlling and/or accessing data storage devices and/or other devices such as input interfaces and output interfaces. The term computer also refers to a plurality of processors or a plurality of (sub) computers that are interconnected and/or connected and/or otherwise communicatively connected and possibly share one or more other resources, such as a memory. A (data) memory is a hard drive (HDD), for example or a (non-volatile) solid state memory, for example a ROM memory or flash memory (Flash EEPROM). The memory often comprises a plurality of individual physical units or is distributed across a large number of separate devices, so that it can be accessed via data communication, for example package data service. The latter is a remote solution, in which memory and processors of a plurality of separate computers are used instead of a (single) central server or in addition to a central server.

According to a further aspect, a computer program product is proposed on which

a computer program code is stored, wherein the computer program code can be executed on at least one computer such that the at least one computer is prompted to carry out the method according to an embodiment according to the above description, wherein at least one unit of the computer:
is disposed in the motor vehicle; and/or
is configured to communicate with a cloud in which preferably at least part of the computer program code is provided.

A computer program product comprising a computer program code according to Claim 6 is a medium such as RAM, ROM, an SD card, a memory card, a flash memory card or a disc or can be stored on and downloaded from a server. Once the computer program is rendered readable via a readout unit, for example a drive and/or installation, the containing computer program code and method contained therein can be executed by a computer or in communication with a plurality of server units, for example according to the above description.

### BRIEF DESCRIPTION OF THE DRAWINGS

The above-described invention is discussed in detail in the following in the context of the relevant technical background with reference to the accompanying drawings which show preferred embodiments. The invention is not limited in any way by the purely schematic drawings, whereby it should be noted that the drawings are not true to scale and are not suitable for defining dimensional relationships. The figures show:

FIG. 1: an example of a progression of operating data in a diagram;

FIG. 2: a flow chart of a method for determining an aging state of at least one cell of a battery;

FIG. 3: arranged operating data according to a method according to FIG. 2; and

FIG. 4: a motor vehicle comprising a control device.

### DETAILED DESCRIPTION OF THE INVENTION

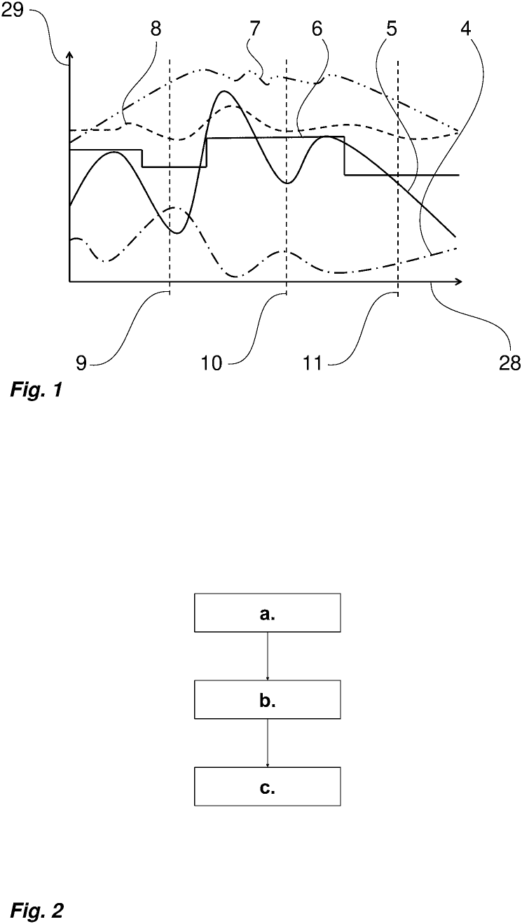

FIG. 1 shows an example of a progression of operating data 4,5,6,7,8 in a diagram. According to the illustration, the time is plotted on the abscissa 28 and the operating data 4,5,6,7,8, which are determined by means of a sensor device 18, for example, are plotted on the ordinate 29. In a method according to FIG. 2, the operating data 4,5,6,7,8 is collected within a few milliseconds, for example every 20 ms (twenty milliseconds). It should be noted that the progressions of the operating data 4,5,6,7,8 shown here are merely examples and are exaggerated for the sake of clarity. Thus, according to the illustration, a first point in time 9 is disposed further away from a second point in time 10 and a third point in time 11 than is envisaged in a real implementation of the method according to FIG. 2. This exaggeration serves only to clarify the time intervals of the method.

The first operating data 4 (plotted in a dash-dot line) represents the resistance within a cell 1 or battery 2. The resistance within a cell 1 or battery 2 is associated with an electrical voltage. The second operating data 5 represents the electric voltage and is shown as a solid line. An interdependency between the electric voltage and the resistance within a cell 1 or battery 2 can clearly be seen here.

The third operating data 6 is plotted above the second operating data 5 in a square wave signal, whereby the third operating data 6 in this design example corresponds to a driving mode setting of an electric drive motor. The driving mode setting corresponds to the maximum power output, which can be assigned to the electric drive motor by means of an on-board computer 25, for example. It is thus possible to deduce the driving behavior of the driver by means of the driving mode setting. In this design example, the fourth operating data 7, which are shown according to the illustration in a dash-dot-dot line, represents the air pressure present at a cell 1 or battery 2.

The fifth operating data 8 (shown as a dash-dash line) shows the temperature profile within a cell 1 or battery 2 in the time interval shown here. It can also be seen here that there is an interdependency between the voltage and the temperature within a cell 1.

FIG. 2 shows a flow chart of a method for determining an aging state of at least one cell 1 of a battery 2. In Step a. of the method, a large amount of operating data 4,5,6,7,8 relating to at least one cell 1 or battery 2 is received via a memory unit 3. The operating data 4,5,6,7,8 is assigned to a specific point in time 9.

The memory unit 3 is part of a battery management system, for example, or is connected to a backend or the cloud 27 by means of a wireless connection to the battery 2. The memory unit 3 is disposed within or connected to said battery 2 in a data transmitting manner, so that the various operating data 4,5,6,7,8 can be assigned to a specific point in time 9 and received in the memory unit 3 in Step a.

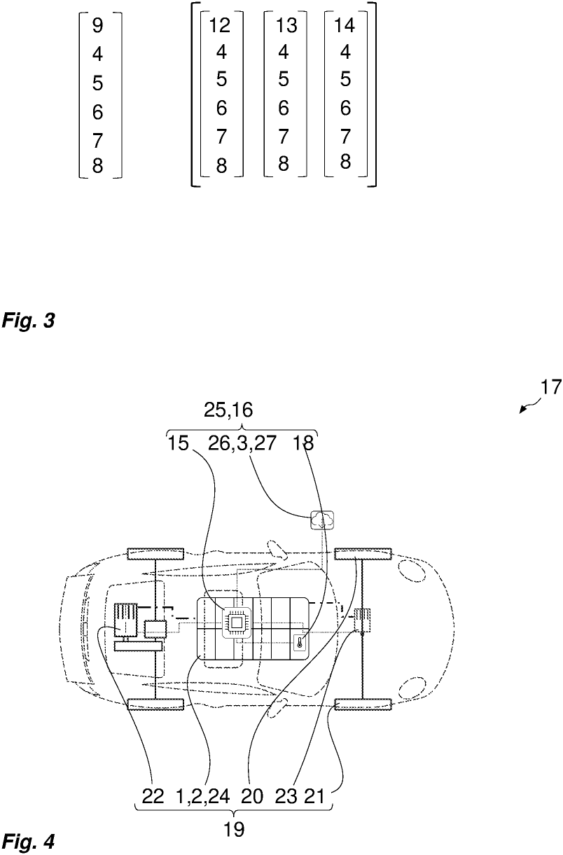

In Step b., the received operating data 4,5,6,7,8 is stored with a timestamp 12 which corresponds to the respectively assigned point in time 9. From the received operating data 4,5,6,7,8, vectors or tuples of operating data 4,5,6,7,8 are provided with a respective timestamp 12,13,14 in Step b., for example, so that a temporal correlation emerges from the various vectors or tuples (see FIG. 3). The timestamps 12,13,14 make it possible to reproduce and sort a load path of a cell 1 and/or battery 2, for example. Within a tuple, the various operating data 4,5,6,7,8 is plotted at a common point in time 9 or timestamp 12, whereby the operating data 4,5,6,7,8 exhibits an interdependency.

In Step c. of the method, an aging state of at least one cell 1 of a battery 2 is calculated by means of a processor 15, taking into account the interdependency of the operating data 4,5,6,7,8 with the associated timestamps 12,13,14. The timestamps 12,13,14 thus provide each tuple with a reproducible temporal dependency both within the tuple and also at least between two tuples.

In Step c., the tuples are arranged in such a way that they span a matrix, whereby timestamps 12,13 enable temporal indexing within the matrix and also allow compression. The matrix can thus be interpreted as an aging model of the battery 2, which is calculated by means of the processor 15 and is expanded at each new timestamp 14. In an advantageous embodiment, when a predefined range of constancy within the operating data 4,5,6,7,8 over a predefined period of time has been determined by the processor 15, a mean value of the operating data 4,5,6,7,8 over said period of time is established and the volume of data is thus compressed.

FIG. 3 shows arranged operating data 4,5,6,7,8 according to a method according to FIG. 2. The operating data 4,5,6,7,8 determined by means of a sensor device 18 and stored in a memory unit 3 can be clearly assigned to a vector or a tuple (on the left according to the illustration) by means of a likewise stored first point in time 9. In Step c. of the method, the thus created vector or tuple is converted by means of a processor 15 into a matrix (on the right according to the illustration) in such a way that a first timestamp 12 of the vector within the matrix replaces an assignable first point in time 9, so that all of the received operating data 4,5,6,7,8 within the matrix comprise a different timestamp 12,13,14 and an aging state of the cell 1 or the battery 2 can be calculated using the internal and external interdependency between the operating data 4,5,6,7,8 and the timestamps 12,13,14.

FIG. 4 shows a motor vehicle 17 comprising a control device 25. The control device 25, which is embodied in this design example as a measuring apparatus 16, comprises a memory unit 3 for storing operating data 4,5,6,7,8, whereby the memory unit 3 in this design example is embodied (purely optionally) as a cloud 27. The cloud 27 is a computer 26, which is location-independently communicatively connected to the motor vehicle 17, so that the received operating data 4,5,6,7,8 can be stored and accessed in the cloud 27. The measuring apparatus 16 further comprises a sensor device 18 which is communicatively connected to the measuring apparatus 16. The sensor device 18 is configured such that operating data 4,5,6,7,8 of a cell 1 of a battery 2 can be determined. The measuring apparatus 16 also comprises a processor 15, which is configured to process the received operating data 4,5,6,7,8 and calculate an aging state of the cell 1 of a battery 2. The measuring apparatus 16 is configured to carry out the method according to FIG. 2.

The motor vehicle 17 further comprises a drive train 19, whereby the drive train 19 comprises a left drive wheel 20 and a right drive wheel 21. The drive train 19 further comprises a first drive motor 22, embodied here as an electric drive motor 22, and a purely optional second drive motor 23, likewise embodied here as an electric drive motor 23. The two drive motors 22,23 are supplied with voltage by a battery 2, whereby the battery 2 here is a traction battery 24. The battery 2 comprises a plurality of cells 1 that store electrical energy in chemical form. This electrical energy is converted to torque by the drive motors 22,23, so that the drive wheels 20,21, which are connected to the drive motors 22,23 in a torque-transmitting manner, convert the torque to propulsion of the motor vehicle 17.

The here proposed method for determining an aging state of at least one cell of a battery makes it possible to estimate an aging state using a multidimensional database.

List of reference signs

| | |
|---|---|
| 1 | Cell |
| 2 | Battery |
| 3 | Memory unit |
| 4 | First operating data |
| 5 | Second operating data |
| 6 | Third operating data |
| 7 | Fourth operating data |
| 8 | Fifth operating data |
| 9 | First point in time |
| 10 | Second point in time |
| 11 | Third point in time |
| 12 | First timestamp |
| 13 | Second timestamp |
| 14 | Third timestamp |
| 15 | Processor |
| 16 | Measuring apparatus |
| 17 | Motor vehicle |
| 18 | Sensor device |
| 19 | Drive train |
| 20 | Left drive wheel |
| 21 | Right drive wheel |
| 22 | First drive motor |
| 23 | Second drive motor |
| 24 | Traction battery |
| 25 | Control device |
| 26 | Computer |
| 27 | Cloud |
| 28 | Abscissa |
| 29 | Ordinate |

What is claimed is:

1. A method for determining an aging state of at least one cell of a battery, said method comprising the following steps:
a. receiving operating data relating to the at least one cell of the battery via a memory unit, wherein the operating data can be assigned to a specific point in time;
b. storing the received operating data in the memory unit with a timestamp which corresponds to the respectively assigned point in time; and
c. calculating an aging state of the at least one cell of the battery using a processor while interdependently taking into account multiple operating data having a common timestamp.

2. The method according to claim 1, wherein the calculation in step c. is carried out on a basis of empirical and/or phenomenological data stored in the memory unit and/or available to the memory unit.

3. The method according to claim 1, wherein the calculation in step c. is carried out using a machine learning algorithm.

4. A measuring apparatus for a battery of a motor vehicle, said measuring apparatus comprising:
at least one sensor device for acquiring operating data relating to at least one cell of the battery;
at least one memory unit for storing operating data from the at least one sensor device; and
at least one processor for processing the operating data,
wherein the measuring apparatus is configured for:
(i) receiving the operating data relating to the at least one cell of the battery via the memory unit, wherein the operating data can be assigned to a specific point in time;
(ii) storing the received operating data in the memory unit with a timestamp which corresponds to the respectively assigned point in time; and
(iii) calculating an aging state of the at least one cell of the battery using the processor while interdependently taking into account multiple operating data having a common timestamp.

5. A motor vehicle comprising:
the measuring apparatus according to claim 4; and
a drive train and at least one drive wheel, wherein the drive train comprises an electric drive motor and a traction battery for propulsion of the motor vehicle,
wherein the electric drive motor, which is supplied with electrical voltage by the traction battery, is connected to the at least one drive wheel in a torque-transmitting manner.

6. A computer program comprising:
a computer program code that can be executed on at least one computer, wherein at least one unit of the computer (i) is disposed in a motor vehicle, and/or (ii) is configured to communicate with a cloud in which at least part of the computer program code is provided,
wherein the at least one computer is prompted for:
a. receiving operating data relating to at least one cell of a battery of the motor vehicle via a memory unit, wherein the operating data can be assigned to a specific point in time;
b. storing the received operating data in the memory unit with a timestamp which corresponds to the respectively assigned point in time; and
c. calculating an aging state of the at least one cell of the battery using a processor while interdependently taking into account multiple operating data having a common timestamp.

7. A computer program product comprising the computer program of claim 6 in which the computer program code is stored.
